(19) United States
(12) Patent Application Publication
(10) Pub. No.: US 2026/0038624 A1
(43) Pub. Date: Feb. 5, 2026

(54) Testmode Revision Control Circuitry

(71) Applicant: Micron Technology, Inc., Boise, ID (US)

(72) Inventors: Roman A. Royer, Boise, ID (US); Nathaniel J. Meier, Boise, ID (US)

(21) Appl. No.: 19/188,851

(22) Filed: Apr. 24, 2025

Related U.S. Application Data
(60) Provisional application No. 63/677,055, filed on Jul. 30, 2024.

(51) Int. Cl. G11C 29/56; G11C 17/14

(52) U.S. Cl. CPC G11C 29/56008; G11C 17/14

(57) ABSTRACT

A memory device includes mode operation circuitry configured to provide use of one or more testmodes during operation of the memory device. The memory device also includes testmode revision control circuitry configured to control enablement of the one or more testmodes via the mode operation circuitry based at least in part on a revision of material of the memory device. The testmode revision control circuitry includes comparison circuitry configured to compare stored bits with testmode bits in a BIOS or firmware of the memory device. The testmode revision control circuitry also includes an output configured to output a latch enable signal to enable the one or more testmodes based at least in part on the comparison of fuse bits with the testmode bits.

### CROSS-REFERENCE TO RELATED APPLICATIONS

This application claims priority to U.S. Provisional Application No. 63/677,055, filed Jul. 30, 2024, which is incorporated by reference herein in its entirety.

### BACKGROUND

### Field of the Present Disclosure

Embodiments of the present disclosure relate generally to semiconductor devices (e.g., memory devices). More specifically, embodiments of the present disclosure relate to managing testmodes for revisions of material of the semiconductor devices.

### Description of Related Art

Generally, a computing system may include electronic devices that, in operation, communicate information via electrical signals. These systems often use testmodes that users/customers may use to address issues found in previous manufacturing batches or during system start up. When later manufacturing batches are deployed, these testmodes may become unnecessary or even counterproductive. However, such usage of testmodes may be dependent on the version of material used by the users/customers. For instance, first testmodes may apply to a first version of a material while such issues are addressed in later versions where the testmode should not be included. Likewise, the second version may have its second testmodes that are not applicable to the first version. The users may not or may be unable to track which devices are made using which version of material to align testmodes to the appropriate version of material. Indeed, this may be more difficult in fast emerging technologies (e.g., such as high-bandwidth memory (HBM)) that has rapid changes and/or mixes of versions of different semiconductor devices in a single package especially since differentiating testmodes may require updates to firmware/BIOS and/or a mechanism for identifying the version of the material. For many such reasons, the users/customers may be agnostic of such changes in material as long as the deployed devices work across materials. Indeed, users/customers may not want to have to track such versions across production and/or deployment.

Embodiments of the present disclosure may be directed to one or more of the problems set forth above.

### BRIEF DESCRIPTION OF THE DRAWINGS

FIG. 1 is a simplified block diagram illustrating certain features of a memory device having testmode circuitry and testmode revision control circuitry (TRCC), according to an embodiment of the present disclosure;

FIG. 2 is a diagram of a package that includes multiple die that may include the memory device of FIG. 1, according to an embodiment of the present disclosure;

FIG. 3 is a circuit diagram of an embodiment of the TRCC of FIG. 1, according to an embodiment of the present disclosure;

FIG. 4 is a diagram of a process having different versions of a material of the memory device of FIG. 1 and different BIOSes and using the TRCC of FIG. 1 to manage enabled testmodes for the memory device, according to an embodiment of the present disclosure;

FIG. 5 is a flow diagram of a process for updating a BIOS/firmware to control testmode activation in a deployed material, according to an embodiment of the present disclosure; and

FIG. 6 is a flow diagram of a process for managing testmode based on revisions to material of the memory device of FIG. 1 using the TRCC of FIG. 1, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As previously mentioned, testmodes may be used to address issues in a version of material for a semiconductor device (e.g., a memory device). As discussed below, testmode revision control circuitry (TRCC) may be deployed in a semiconductor device. As discussed below, the TRCC may be used to decode which testmodes apply to the semiconductor device based on a version of material used in implementing the semiconductor device. The TRCC decodes which testmodes to apply and maps the proper testmodes. The TRCC compares fused bits to bits indicated in a BIOS/firmware version to determine whether corresponding testmodes should be active. As discussed below, if the bits match the proper pattern, the corresponding testmodes are enabled. In some embodiments, a bypass bit may be used to enable testmodes regardless of comparison outcomes.

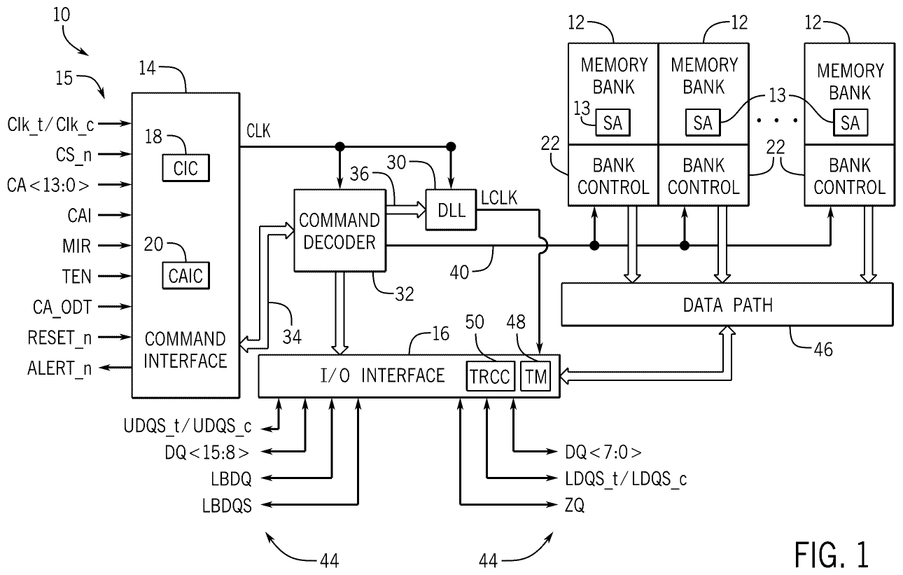

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random-access memory (DDR5 SDRAM) device. Various features of DDR5 SDRAM allow for reduced power consumption, more bandwidth and more storage capacity compared to prior generations of DDR SDRAM. Furthermore, although the following discussion relates to DDR5 memory device, the testmode revision control scheme discussed herein may be likewise applied to any memory device of any suitable type that may have different testmodes between material revisions. Indeed, the testmode revision control scheme discussed herein may be applied to semiconductor devices beyond just memory devices for any semiconductor devices that may have different testmodes between material revisions.

The memory device 10 may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIM M may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabyte (Gb) DDR5 SDRAM, the memory chip may include 16 memory banks 12, arranged into 8 bank groups, each bank group including 2 memory banks. For a 16 Gb DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application and design of the overall system.

The memory banks 12 and/or bank control blocks 22 include sense amplifiers 13. As previously noted, sense amplifiers 13 are used by the memory device 10 during read operations. Specifically, read circuitry of the memory device 10 utilizes the sense amplifiers 13 to receive low voltage (e.g., low differential) signals from the memory cells of the memory banks 12 and amplifies the small voltage differences to enable the memory device 10 to interpret the data properly.

The memory device 10 may include a command interface 14 and an input/output (I/O) interface 16. The command interface 14 is configured to provide a number of signals (e.g., signals 15) from an external (e.g., host) device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, the true clock signal Clk_t and the bar clock signal Clk_c. The positive clock edge for DDR refers to the point where the rising true clock signal Clk_t crosses the falling bar clock signal Clk_c, while the negative clock edge indicates that transition of the falling true clock signal Clk_t and the rising of the bar clock signal Clk_c. Commands (e.g., read command, write command, etc.) are typically entered on the positive edges of the clock signal and data is transmitted or received on both the positive and negative clock edges.

The clock input circuit 18 receives the true clock signal Clk_t and the bar clock signal Clk_c and generates an internal clock signal CLK. The internal clock signal CLK is supplied to an internal clock generator, such as a delay locked loop (DLL) circuit 30. The DLL circuit 30 generates a phase controlled internal clock signal LCLK based on the received internal clock signal CLK. The phase controlled internal clock signal LCLK is supplied to the I/O interface 16, for instance, and is used as a timing signal for determining an output timing of read data. In some embodiments, the clock input circuit 18 may include circuitry that splits the clock signal into multiple (e.g., 4) phases. The clock input circuit 18 may also include phase detection circuitry to detect which phase receives a first pulse when sets of pulses occur too frequently to enable the clock input circuit 18 to reset between sets of pulses.

The internal clock signal(s)/phases CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the DLL circuit 30 over the bus 36 to coordinate generation of the phase controlled internal clock signal LCLK. The phase controlled internal clock signal LCLK may be used to clock data through the IO interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes the bank control block 22 which provides the necessary decoding (e.g., row decoder and column decoder), as well as other features, such as timing control and data control, to facilitate the execution of commands to and from the memory banks 12.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20, which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a testmode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity testmode executed using the TEN signal, as described above.

Data may be sent to and from the memory device 10, utilizing the command and clocking signals discussed above, by transmitting and receiving data signals 44 through the IO interface 16. More specifically, the data may be sent to or retrieved from the memory banks 12 over the data path 46, which includes a plurality of bi-directional data buses. Data IO signals, generally referred to as DQ signals, are generally transmitted and received in one or more bi-directional data busses. For certain memory devices, such as a DDR5 SDRAM memory device, the IO signals may be divided into upper and lower bytes. For instance, for a x16 memory device, the IO signals may be divided into upper and lower IO signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance. As previously discussed, the memory device 10 may include testmode (TM) circuitry or mode operation circuitry 48 that is used to implement one or more modes of operation/testmodes for the memory device 10. For instance, testmodes may be used to adjust operations to compensate for known issues using corresponding changes, such as trim changes, reticle changes, or other changes. As previously noted, between different materials/versions of the memory device 10 different issues may present to where different testmodes may be applicable to different versions/materials for implementation of the memory device 10. For instance, a first version of the memory device 10 may use testmodes to fix issues that are fixed in the silicon of a second version of the memory device 10. Accordingly the second version may not use all of the testmodes that the first version uses. For any issues not fixed between the first and second versions, the testmodes may remain enabled. Additionally, the second version of the memory device 10 may have different issue(s) that may be addressed using additional testmodes that the first version does not need/use. Accordingly, it may be desirable for the memory device 10 to track and control testmode mapping beyond BIOS and/or firmware that may be updated to remain generic between versions/revisions/material. As discussed below, testmode revision control circuitry (TRCC) 50 may be used to control which testmodes are enable for a material (or version/revision) of the memory device 10. As discussed below, the TRCC 50 compares bits (e.g., fuses) stored in the material based on the material type with other bits (e.g., in basic input/output system (BIOS) or firmware) for the memory device 10. Based on matching and/or mismatching patterns due to the comparison, the TRCC 50 may cause one or more corresponding testmodes to be enabled/disabled. In some embodiments, the TRCC 50 may be implemented in a different location than the TM circuitry 48 to enable implementations in devices without modification of the TM circuitry 48.

Returning to FIG. 1, an impedance (ZQ) calibration signal may also be provided to the memory device 10 through the IO interface 16. The ZQ calibration signal may be provided to a reference pin and used to tune output drivers and ODT values by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback data signal (LBDQ) and loopback strobe signal (LBDQS) may be provided to the memory device 10 through the IO interface 16. The loopback data signal and the loopback strobe signal may be used during a test or debugging phase to set the memory device 10 into a mode wherein signals are looped back through the memory device 10 through the same pin. For instance, the loopback signal may be used to set the memory device 10 to test the data output (DQ) of the memory device 10. Loopback may include both LBDQ and LBDQS or possibly just a loopback data pin. This is generally intended to be used to monitor the data captured by the memory device 10 at the IO interface 16. LBDQ may be indicative of a target memory device, such as memory device 10, data operation and, thus, may be analyzed to monitor (e.g., debug and/or perform diagnostics on) data operation of the target memory device. Additionally, LBDQS may be indicative of a target memory device, such as memory device 10, strobe operation (e.g., clocking of data operation) and, thus, may be analyzed to monitor (e.g., debug and/or perform diagnostics on) strobe operation of the target memory device.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description. Furthermore, although the foregoing discusses the memory device 10 as being a DDR5 device, the memory device 10 may be any suitable device (e.g., a double data rate type 4 DRAM (DDR4), a ferroelectric RAM device, an HBM (high bandwidth memory) device, or a combination of different types of memory devices).

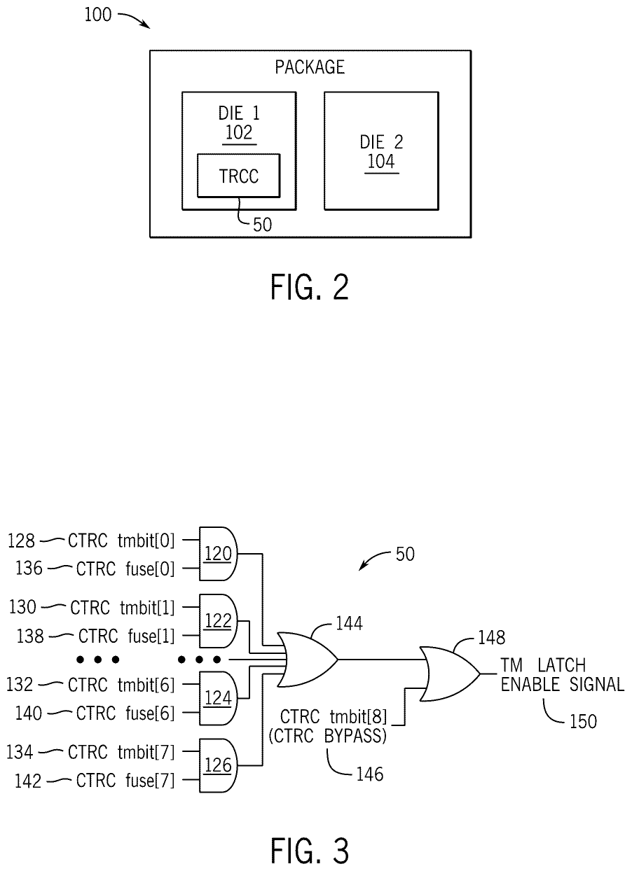

As previously noted, the TRCC 50 may be used in semiconductor devices that include more than one die. For instance, the TRCC 50 may be used in a package, such as a package 100 illustrated in FIG. 2. As illustrated, the package 100 includes a first die 102 and a second die 104. The first die 102 and/or the second die 104 may include any suitable die, such as memory, storage, processing, and the like. For instance, the package 100 may be a dedicated or a mixed-technology package, such as a high bandwidth memory (HBM), multi-die memory, memory and memory-processing package with CPU/GPU and on-package memory, and/or the like. For instance, the first die 102 may include a memory controller or logic die (e.g., HBM controller die) while the second (and/or other die) include memory storage. In some embodiments, the first die 102 and/or the second die 104 may be stacked die (e.g., HBM).

Since the first die 102 and the second die 104 may be heterogenous of different types and/or revisions, the package 100 may have dies with different revision cycles. In other words, the first die 102 and/or the second die 104 may be revised more frequently/rapidly than the other die. Accordingly, different packages may have different mixtures of revisions of the first die 102 or the second die 104 while the other revisions remain the same. This, potentially issue exacerbates any issues in tracking and maintaining testmode mapping. Thus, it may be advantageous for the package 100 to maintain testmodes control/mapping for at least one of its die. The first die 102 includes the TRCC 50. In some embodiments, the second die 104 may include its own TRCC 50. The TRCC 50 may be used to map testmodes for the first die 102, the second die 104, and/or the package 100.

FIG. 3 is a circuit diagram of the TRCC 50 of FIG. 1. As illustrated, the TRCC 50 utilizes customer testmode revision control (CRTC) testmode bits or operation mode bits (tmbits) and CTRC fuses to determine which testmodes to enable. The CRTC tmbits indicate one or more testmodes that are to be enabled by the customer BIOS and/or firmware. As previously noted, the customer BIOS and/or firmware may be generic to multiple different revisions of the memory device 10. Accordingly, the TRCC 50 also uses the CTRC fuses that are used to indicate which testmodes are to be enabled for the specific revision of the semiconductor implementation of the memory device 10. The CTRC tmbits may be appended to testmode addresses. In the illustrated embodiment of the TRCC 50, the TRCC 50 uses 8+1 tmbits with 8 tmbits each corresponding to one or more testmodes based on a comparison with the CTRC fuses. The 8+1 tmbits also uses 1 tmbit to bypass comparison of the tmbits to CTRC fuses and force enabling all testmodes. Thus, when a customer/customer's BIOS/customer's firmware attempts to latch a testmode, the TRCC 50 compares corresponding tmbits and fuses. If both values are a logic high, the testmode may be enabled. As such, in some embodiments, different instances of the TRCC 50 may be deployed for each testmode/group of testmodes that may be enabled. For instance, the illustrated TRCC 50 may utilize all tmbits and corresponding fuses, but some testmodes/groups of testmodes may use/compare only a portion of the values, such as 1, 2, 3, or more tmbit-fuse comparisons to enable the corresponding testmode/group of testmodes.

As illustrated, TRCC 50 includes AND gates 120, 122, 124, and 126 along with any non-illustrated similar AND gates for any other tmbit-fuse comparisons that may be performed. The AND gate 120 receives CTRC tmbit[0] 128, the AND gate 122 receives CTRC tmbit[1] 130, the AND gate 124 receives CTRC tmbit[6] 132, and the AND gate 126 receives CTRC tmbit[7] 134. The AND gate 120 also receives CTRC fuse[0] 136, the AND gate 122 also receives CTRC fuse[1] 138, the AND gate 124 also receives CTRC fuse[6] 140, and the AND gate 126 also receives CTRC fuse[7] 142. The AND gate 120 compares the CTRC tmbit[0] 128 with the CTRC fuse[0] 136 using an AND operation outputting a logic high only when both are asserted. The AND gate 122 compares the CTRC tmbit[1] 130 with the CTRC fuse[1] 138 using an AND operation outputting a logic high only when both are asserted. The AND gate 124 compares the CTRC tmbit[6] 132 with the CTRC fuse[6] 140 using an AND operation outputting a logic high only when both are asserted. Likewise, the AND gate 126 compares the CTRC tmbit[7] 134 with the CTRC fuse[7] 142 using an AND operation outputting a logic high only when both are asserted. The outputs of the AND gates 120, 122, 124, and 126 may be transmitted to an OR gate 144 that causes the testmode/group of testmodes to be enabled if any compared tmbit and fuse values are both high.

As previously noted, one CTRC fuse may be used as a bypass of the comparisons by causing the testmode/group of testmodes to be enabled regardless of the results of the comparisons. As illustrated, CTRC tmbit[8] 146 may be a bypass bit that is transmitted to an OR gate 148 along with an output of the OR gate 144 that causes a test mode to be enabled using TM latch enable signal 150. In other words, the CTRC tmbit[8] 146 is a bypass bit that is used to bypass the comparison logic to force the respective testmode to be enabled.

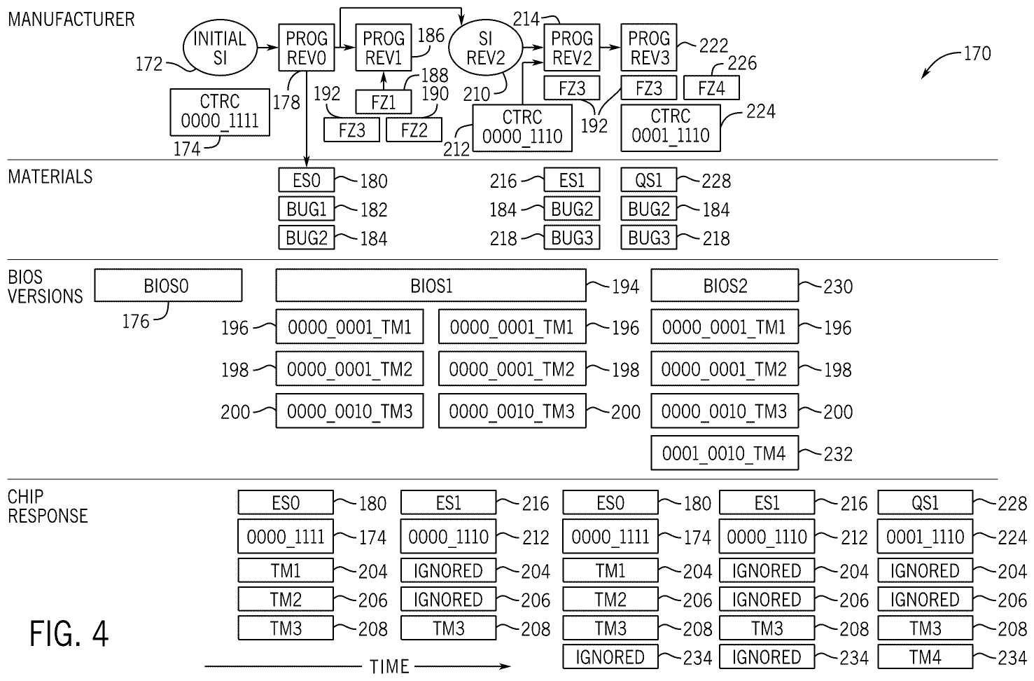

FIG. 4 is a block diagram of testmode revision control using the TRCC 50 over time. The memory device 10 is developed with an initial revision/first material 172 using silicon and/or another semiconductor. With the implementation, the CTRC fuses are set with a value 174 and has an initial BIOS (Bios0) 176. The value indicates that some fuses (e.g., 1s) corresponding to testmodes/testmode groups are initially enabled for the memory device 10 while others (e.g., 0s) are disabled and reserved for future use if the initial testmodes are consumed. Furthermore, the initial testmodes may be disabled by blowing the fuses in future materials if the testmodes no longer apply. In summary, by enabling a portion of fuses on the material indicates a fuse version (e.g., 0000_1111) where initial testmodes are enabled for later determined issues for that initial manufacture that are to be corrected using testmodes that may be enabled by updating the BIOS/firmware. In some embodiments, the Bios0 176 may enable none of the testmodes until the BIOS is updated to a new version.

Using revision 0 (rev0) programming 178, a first material 180 is produced. The first material 180 may be an initial revision/engineering sample 0 (ESO) 180. Before, manufacturing, during manufacture, and/or during testing, the customer and/or manufacturer discovers issues: bug1 182 and bug2 184. Both bugs may be addressed using revision 1 (rev1) programming 186 that corresponds testmodes to CTRC fuses 188, 190, and 192 that were initially enabled by the value 174. The identified issues may be fixed using one or more testmodes. For instance, one issue (e.g., a reticle issue) may be resolved using first and second testmodes. That are latched to CTRC fuses 188 and 190. Since both testmodes may be for the same issue, both testmodes may be mapped to a single CTRC fuse 188 or 190. As such, each fuse may correspond to a single testmode or to a group of testmodes. The CTRC fuse 190 may correspond to another testmode used to fix a different issue, bug2 184. As previously noted, the CTRC fuses 188, 190, and 192 may be mapped to initially enabled bits. Thus, when the rev1 programming 186 results in a new BIOS revision (Bios1) 194, corresponding testmodes may be enabled. For instance, the Bios1 194 may include a tmbit 196 that corresponds to testmode1 (TM 1), a tmbit 198 that corresponds to testmode2 (TM 2), and a tmbit 200 that corresponds to a testmode3. As previously noted, TM 1 and TM 2 may be directed to the same issue (e.g., reticle issue) and may be grouped to a same fuse value (e.g., bit0/least significant bit (LSB) in the value 174). TM 3, being directed to the bug 184, may be grouped to a different fuse value (e.g., bit1/second LSB in the value 174). In other words, in the illustrated embodiment, each group of testmodes may correspond to a specific column in the value 174. Since TM 1, TM 2, and TM 3 map to enabled bits (bit0, bit0, and bit1, respectively) in the value 174, enabling the tmbits in the Bios1 194 results in the ESO 180 material (or revision) of the memory device 10 to have enabled TM 1 204, TM 2 206, and TM 3 208.

Later, a second material 210 is produced. The second material 210 may be a design update to a chip implementation on a semiconductor (e.g., silicon). The later shipment of the second material 210 may enable the second material 210 to address at least some of the issues in the first material 172. For instance, the second material 210 may correct the bug 182 thereby meaning that TM 1 204 and TM 2 206 are not needed/should not be used. Accordingly, the second material 210 has only fuse 192 set by changing a value (bit0) in the value 174 to store a value 212 in revision 2 (rev2) programming 214. The rev2 programming 214 may be used to ship the second material 210 as samples 216 (engineering samples 1 (ES1)). The rev2 programming 214 disables the TM 1 204 and TM 2 206 despite still being included in the Bios due to the comparison in the TRCC 50 of the tmbits and fused values. In some embodiments, the fuse(s) that corresponded to TM 1 204 and TM 2 206 may be prevented from being reused for future issues for the second material 210, but in some embodiments, the fuse(s) may be reused for different bugs in different materials, such as the second material 210 may use bit0 for different testmodes since the bug1 182 and TM 1 204 and TM 2 206 does not apply to the second material 210 or if the testmodes for bug1 182 no longer have any impact on the second material 210. Since the value 212 contains a logic high value corresponding to the TM 3 208 and a logic high value in the tmbit, the TM 3 208 remains latched/enabled in the memory device 10 on the second material 210.

At some point during manufacture, after manufacture, and/or during testing, a new issue: bug3 218 is discovered by the manufacturer and/or customer. This bug3 218 may be addressed with a new programming revision (rev3) 222 that is used to address the bug3 218. In the illustrated embodiment, a new fuse 226 is set for value 224. The programming rev3 222 may be used for new samples (e.g., qualification samples (QS1)) along with an update to the BIOS to Bios2 230. As illustrated, Bios2 230 may use tmbits 196, 198, 200, and 232 to allow the BIOS to attempt to enable TM 1 204, TM 2 206, TM 3 208, and a testmode4 (TM 4) 234. However, as previously noted, the TRCC 50 may determine whether a particular testmode is enabled using both the tmbits and the fuse pattern for the particular material. Thus, even when Bios2 230 attempts to enable TM 1 204, TM 2 206, TM 3 208, and TM 4 234, whether those testmodes are enabled depends on the material (e.g., ES0 180, ES1 216, QS1 228, etc.) on which a particular memory device 10 is implemented. In other words, different material/revisions of the memory device 10 may react differently for the same BIOS. This, material specific-response enables changes to be made on a material-specific basis without requiring the customer to update/change BIOS versions and/or settings in the BIOS. Indeed, the customer does not have track such changes and may even be unaware of such differences between material implementations.

For example, in the foregoing example discussed in relation to FIG. 4, ES0 180 running Bios1 194 will enable TM 1 204, TM 2 206, and TM 3 208 due to the value 174 (“fuse bit pattern”) and the tmbits of Bios1 194 both enabling the TM 1 204, TM 2 206, and TM 3 208. ES1 216 running Bios1 194 will enable only TM 3 208 while ignoring TM 1 204 and TM 2 206 due to the value 212 not enabling TM 1 204 and TM 2 206 even though Bios 194 includes TM 1 204, TM 2 206, and TM 3 208. ES0 180 running Bios2 230 will enable TM 1 204, TM 2 206, and TM 3 208 while ignoring TM 4 234 since it is not enabled in the fuse pattern/value 174. Likewise, ES1 216 running Bios2 230 will enable only TM 3 208 while ignoring TM 1 204, TM 2 206, and TM 4 234, due to the value 212 not enabling TM 1 204, TM 2 206, and TM 4 234. Similarly, QS1 228 running Bios2 230 will enable only TM 3 208 and TM 4 234 while ignoring TM 1 204 and TM 2 206 due to the value 224.

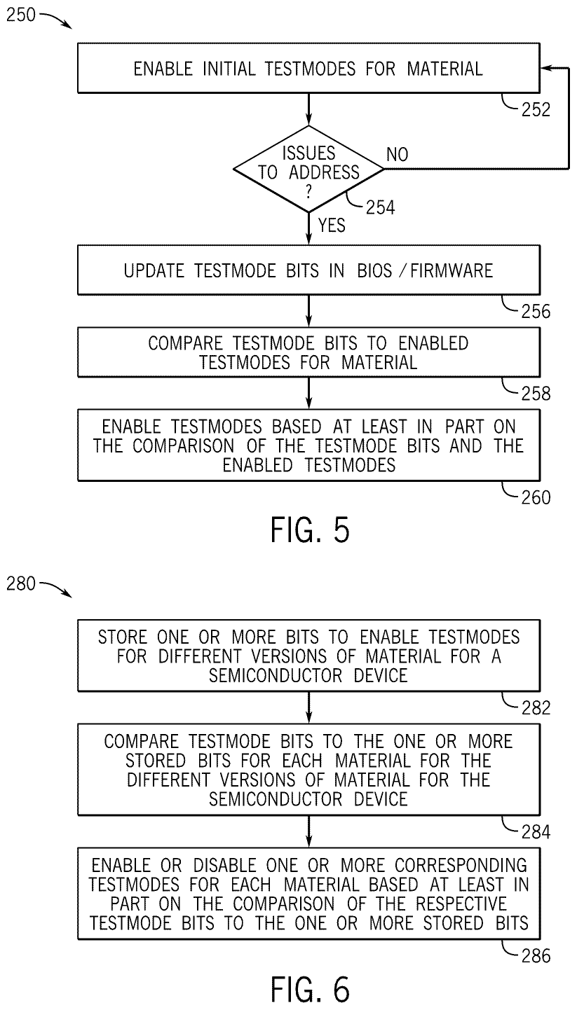

FIG. 5 is a flow chart of a process 250 for utilizing the TRCC 50. Initially, a manufacturer enables initial testmodes for a material (block 252). For instance, the manufacturer may set fuses for the material based on an initial configuration. For instance, some bits may be set to a first value (e.g., 1) to enable initial testmodes to be used while other bits are set to a second value (e.g., 0) to disable them reserve them for future use. Once issues to address are identified (block 254), the manufacturer (and/or customer) may update testmode bits in the BIOS and/or firmware (block 256). For instance, the manufacture may release a new BIOS or firmware version that maps specific testmode bits to specific testmodes that may be enabled in the TM 48. The TRCC 50 then compares the testmode bits in the BIOS and/or firmware to enabled testmode bits for the specific material (block 258). For instance, as previously discussed, this comparison may be a bit-to-bit comparison. In certain embodiments, which testmodes are enabled may be determined on an overall pattern. For instance, each set of testmodes may be enabled when a corresponding pattern is present in the tmbits and the fuse pattern. For instance, a pattern 0000111X may indicate a pattern of zeros, ones, and X for determining which testmodes to enable. X may be a wildcard that can be a 1 or a 0 and still match patterns between the fuse pattern and the tmbits. Furthermore, although the number of fuse bits and tmbits discussed herein use 8 bits, any suitable number of bits may be used with more bits providing more flexibility but with an increased cost in area and materials as a tradeoff for the increased flexibility or the number of bits may be reduced to reduce such costs. In some embodiments, the memory device 10 may have a unique identifier (e.g., fuse ID) that identifies the device and/or its material. Part or all of this unique identifier could also be used to control which testmodes are enabled or disabled on specific material. Returning to FIG. 5, based on this comparison, the TRCC 50 enables at least one testmode (block 260).

FIG. 6 is a flow diagram of a process 280 for utilizing the material-specific testmodes. The process 280 includes storing one or more stored bits to enable testmodes for different versions of material for a semiconductor device (e.g., the memory device 10) (block 282). Enabling the testmodes includes the materials having different fuse values, fuse patterns, and/or fuse identifiers that identify which materials are used for the different versions of the semiconductor device. These values may be stored by the manufacturer during the manufacturing process and/or added after manufacture. The TRCC 50 of each version of material then compares the one or more stored bits/enabled testmode to testmode bits (tmbits) to determine which testmodes are compatible/to-be-used by the corresponding versions of material (block 284). For instance, the TRCC 50 may perform a bitwise comparison of fuse bits to tmbits in BIOS/firmware to determine which testmodes are to be used. The TRCC 50 then enables or disables one or more corresponding testmodes for each material based at least in part on the comparison of the respective testmode bits to the one or more stored bits (block 286). As previously noted, this varied response by different versions of material frees the customer/user from needing to tracking and maintaining which versions of a material use which BIOS/firmware and/or changing settings on the device. In fact, the customer/user need not be involved or even aware of different versions of material and their different available testmodes.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A memory device, comprising:
mode operation circuitry configured to provide use of one or more operation modes; and
operation mode revision control circuitry configured to control enablement of the one or more operation modes via the mode operation circuitry based at least in part on a revision of material of the memory device, wherein the operation mode revision control circuitry comprises:
comparison circuitry configured to compare stored bits with operation mode bits externally provided to the memory device; and
an output configured to output a latch enable signal to enable the one or more operation modes based at least in part on the comparison of fuse bits with the operation mode bits.

2. The memory device of claim 1, comprising fuse bits configured to store the stored bits.

3. The memory device of claim 1, wherein the stored bits comprise material-specific patterns stored to indicate which operation modes are applicable to a specific revision of material of the memory device.

4. The memory device of claim 1, wherein the comparison circuitry comprises a plurality of AND gates that each receive a respective operation mode bit and a corresponding stored bit.

5. The memory device of claim 4, wherein the comparison circuitry comprises an OR gate configured to receive outputs of the plurality of AND gates as inputs to the OR gate, and an output of the OR gate is an output from the comparison.

6. The memory device of claim 5, wherein the comparison circuitry comprises a bypass circuit that is configured to bypass the comparison and enable the operation mode bits to enable any of the one or more operation modes.

7. The memory device of claim 6, wherein the bypass circuit is configured to receive an output from the comparison and a bypass bit both as inputs to a bypass OR gate that outputs the latch enable signal.

8. The memory device of claim 1, wherein the externally provided bits are provided by a BIOS or firmware of the memory device, and wherein the operation mode revision control circuitry is configured to confirm that each of the one or more operation modes is enabled for both the revision of the material and for the operation mode addresses being loaded by each version of the BIOS or firmware.

9. The memory device of claim 1, wherein the stored bits comprise a fuse identifier for the memory device.

10. The memory device of claim 1, wherein the comparison of the stored bits and the operation mode bits comprises matching a pattern of the stored bits and the operation mode bits.

11. The memory device of claim 10, wherein the pattern comprises at least one wildcard bit that is satisfied by any value.

12. A method for operating an electronic device, comprising:
enabling initial testmodes for a material version of the electronic device by storing corresponding bits in the electronic device;
updating testmode bits for the electronic device to address operational issues;
comparing, in testmode revision control circuitry, the testmode bits to enabled testmodes for the material version of the electronic device; and
enabling, via the testmode revision control circuitry, one or more of the initial testmodes based at least in part on the comparison of the testmode bits with the enabled testmodes for the material version of the electronic device.

13. The method of claim 12, wherein updating the testmode bits comprises updating a BIOS or firmware of the electronic device.

14. The method of claim 13, wherein updating the testmode bits comprises identifying an issue and updating the BIOS or firmware to allow the BIOS or firmware to allow the one or more initial testmodes to address the issue.

15. The method of claim 12, wherein the one or more of the initial testmodes comprises adjusting trims or functionality associated with specific reticle changes.

16. The method of claim 12, comprising enabling a new testmode in a subsequent material version of the electronic device.

17. The method of claim 12, comprising disabling at least one of the one or more of the initial testmodes in a subsequent material version of the electronic device.

18. A method for operating a semiconductor device, comprising:
storing one or more stored bits to enable testmodes for different versions of material for the semiconductor device;
comparing testmode bits to the one or more stored bits for each material for the different versions of materials for the semiconductor device using respective testmode revision control circuitries of the different versions of material; and
enabling or disabling, using the respective testmode revision control circuitries, one or more corresponding testmodes for each material based at least in part on the comparison of the respective testmodes to the one or more stored bits.

19. The method of claim 18, wherein the stored comprise bits stored in fuses of the semiconductor device.

20. The method of claim 18, wherein the different versions of material for the semiconductor device comprise different samples of the semiconductor device at different times of manufacture of the semiconductor device.
